(19) United States
(12) Patent Application Publication
(10) Pub. No.: US 2015/0131211 A1
(43) Pub. Date: May 14, 2015

(54) FIXING DEVICE OF ELECTRONIC ELEMENT

(71) Applicant: DELTA ELECTRONICS, INC., Taoyuan Hsien (TW)

(72) Inventors: Po-Lin PAN, Taoyuan Hsien (TW); Yuh-Chu SU, Taoyuan Hsien (TW); Chia-Chi WU, Taoyuan Hsien (TW)

(73) Assignee: DELTA ELECTRONICS, INC., Taoyuan Hsien (TW)

(21) Appl. No.: 14/248,710

(22) Filed: Apr. 9, 2014

(30) Foreign Application Priority Data
Nov. 12, 2013 (TW) 102141131

(51) Int. Cl. H05K 5/02

(52) U.S. Cl. CPC H05K 5/0217; H05K 5/0247
USPC 361/679.01

(57) ABSTRACT

A fixing device of electronic element comprises a main body and a hook. The main body contains an electronic element and comprises a guiding groove and a block. The guiding groove is disposed at a sidewall of the main body. The block is disposed on a side of the guiding groove and has a blocking surface. The hook is disposed in the guiding groove to fix the electronic element and comprises a body, a pressing portion, a cantilever and a cushion structure. The pressing portion is disposed on one end of the body. The cantilever has a contact surface to press the blocking surface. Two ends of the cushion structure are connected to the other end of the body and the cantilever, respectively.

### CROSS REFERENCE TO RELATED APPLICATIONS

This Non-provisional application claims priority under 35 U.S.C. §119(a) on Patent Application No(s). 102141131 filed in Taiwan, Republic of China on Nov. 12, 2013, the entire contents of which are hereby incorporated by reference.

### BACKGROUND OF THE INVENTION

1. Field of Invention

The invention relates to a fixing device and, in particular, to a fixing device for fixing electronic element.

2. Related Art

Generally, an electronic element is fixed by being disposed in a container including a hook disposed at and extended from the edge, and a protruding hook portion is formed on the top end of a main body of the hook. When the electronic element is disposed in the container, the main body can tightly contact the sidewall of the electronic element while the hook portion presses the top surface of the electronic element, and therefore the electronic element is fixed in the container.

Because the container and the hook are integrally formed as one piece, the hook needs to be pulled open outwardly so that the electronic element can be disposed in or removed from the container during the assembly or disassembly process. However, when the hook is pulled outwardly, the main body of the hook will undergo extremely large stress and is thus easily damaged or broken. Currently, by precisely calculating the force balance among the hook, the container and the electronic element, the hook can be avoided from being damaged, but this brings limited effect.

Besides, for making the hook precisely contact the top surface of the electronic element so that the electronic element will not be shaken too much even if the vibration occurs, the form of the hook needs to match the form of the electronic element. In other words, the length of the main body of the hook needs to be changed according to the height of the electronic element, so the electronic element can not be fixed stably if the tolerance exists between the hook and the container. That is to say, the structure of the conventional hook and container stands for little assembly tolerance and therefore the manufacturing cost will be increased.

Therefore, it is an important subject to provide a fixing device of electronic element which is designed novelly and simply so that the fixing device can undergo less force during the assembly or disassembly process and therefore the lifespan of the fixing device can be increased.

### SUMMARY OF THE INVENTION

In view of the foregoing subject, an objective of the invention is to provide a fixing device of electronic element which is designed novelly and simply so that the fixing device can undergo less force during the assembly or disassembly process and therefore the lifespan of the fixing device can be increased.

To achieve the above objective, a fixing device of electronic element according to the invention comprises a main body and a hook. The main body contains an electronic element and comprises a guiding groove and a block. The guiding groove is disposed at a sidewall of the main body. The block is disposed on a side of the guiding groove and has a blocking surface. The hook is disposed in the guiding groove to fix the electronic element and comprises a body, a pressing portion, a cantilever and a cushion structure. The pressing portion is disposed on one end of the body. The cantilever has a contact surface to press the blocking surface. Two ends of the cushion structure are connected to the other end of the body and the cantilever, respectively.

In one embodiment, the end of the body near the cantilever has an indentation, the cushion structure is disposed in the indentation and connected to the body, and the length of the indentation is greater than that of the cantilever.

In one embodiment, the hook is detachably disposed in the guiding groove.

In one embodiment, the cantilever includes a cantilever root connected to the cushion structure, and the size of the connection portion of the cantilever root and the cushion structure is less than that of the cantilever and the body.

In one embodiment, the blocking surface has a rough structure.

In one embodiment, the contact surface of the cantilever has a second rough structure.

In one embodiment, the blocking surface is an inclined surface or a curved surface.

In one embodiment, when the hook fixes the electronic element, the pressing portion locks the top end of the electronic element and the contact surface of the cantilever presses the blocking surface.

In one embodiment, when the hook fixes the electronic element, an included angle is formed between the cantilever and the blocking surface and the included angle is between 60° and 100°.

In one embodiment, the pressing portion and the cantilever are extended from the two ends of the body, respectively.

In one embodiment, the pressing portion and the cantilever are extended from the body along different directions.

In one embodiment, the main body further includes an opening, and the opening is disposed at a bottom or the sidewall of the main body.

In one embodiment, the fixing device further comprises a disassembling tool passing through the opening to press the cantilever.

In one embodiment, the body has a first plane contacting the electronic element, and the side of the cantilever near the electronic element has a second plane which doesn't contact the electronic element.

In one embodiment, the second plane is farther from the electronic element than the first plane.

In one embodiment, a width of the body is greater than that of the cantilever.

In one embodiment, the cushion structure is made by an elastic material.

In one embodiment, the elastic material includes plastic material, rubber, silica gel or their combinations.

To achieve the above objective, a fixing device of electronic element according to the invention comprises a main body and a hook. The main body contains an electronic element and comprises a guiding groove and a block. The guiding groove is disposed at a sidewall of the main body. The block is disposed on a side of the guiding groove and has a blocking surface. The hook is used to fix the electronic element and comprises a body a pressing portion a cantilever and a cushion structure. The body includes an indentation, and the pressing portion is disposed on one end of the body. The cantilever has a contact surface. Two ends of the cushion structure are connected to the other end of the body and the cantilever, respectively. When the hook is disposed in the guiding groove, the cantilever is pressed to the indentation by the block, and when the pressing portion fixes the electronic element, the contact surface of the cantilever presses the blocking surface.

As mentioned above, the fixing device of the invention has a main body for containing an electronic element. The main body includes the guiding groove disposed between the main body and the electronic element so that the electronic element can be fixed when the hook is disposed in the guiding groove and the pressing portion presses the top end of the electronic element. In this case, the electronic element is first disposed in the main body and the hook is then disposed in the guiding groove, and therefore the electronic element can be settled during the assembly process without pushing or pulling the body of the hook. Hence, the damage of the hook can be reduced so that the lifespan of the fixing device and the hook can be expanded.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic exploded diagram of a fixing device and an electronic element according to an embodiment of the invention;

FIG. 1B is a schematic enlarged diagram of the hook in FIG. 1A;

FIG. 2A is a schematic diagram showing the case after assembling the main body and the electronic element in FIG. 1A;

FIG. 2B is a schematic diagram showing the case after assembling the fixing device and the electronic element in FIG. 1A;

FIGS. 3A to 3C are schematic diagrams showing the operation of the fixing device in FIG. 1A;

FIG. 4 is a schematic diagram showing another view of the hook in FIG. 1B;

FIG. 5 is a schematic enlarged diagram of the region A of the fixing device in FIG. 3C;

FIG. 6 is a schematic diagram of a fixing device according to another embodiment of the invention; and

FIG. 7 is a schematic diagram of a disassembling tool for the fixing device in FIG. 2B.

### DETAILED DESCRIPTION OF THE INVENTION

The present invention will be apparent from the following detailed description, which proceeds with reference to the accompanying drawings, wherein the same references relate to the same elements.

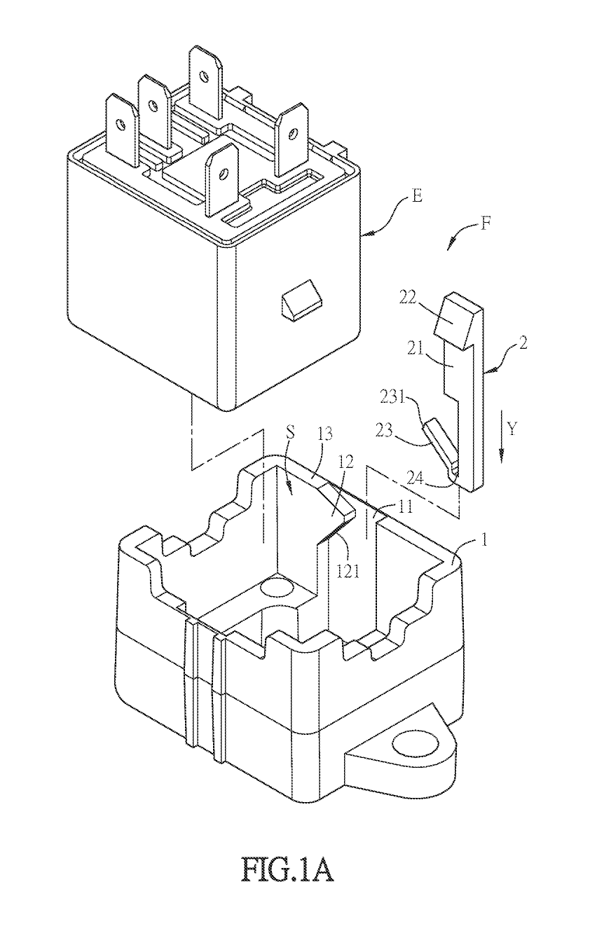

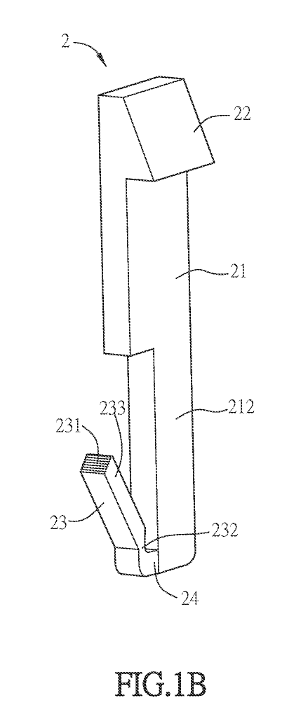

FIG. 1A is a schematic exploded diagram of a fixing device and an electronic element according to a first embodiment of the invention. As shown in FIG. 1A, the fixing device F of the electronic element E is used to fix the electronic element E and includes a main body 1 and a hook 2. The main body 1 has a space S for containing the electronic element E. The main body 1 further includes a guiding groove 11 and a block 12. The guiding groove 11 is disposed at a sidewall 13 of the space S. The hook 2 includes a body 21, a pressing portion 22, a cantilever 23 and a cushion structure 24. The pressing portion 22 is disposed on an end of the body 21 and the cushion structure 24 is connected to the other end of the body 21. In other words, the pressing portion 22 and the cushion structure 24 are disposed on and extended from two ends of the body 21, respectively. The other end of the cushion structure 24 is connected to the cantilever 23, so the two ends of the cushion structure 24 are connected to the end of the body 21 and the cantilever 23, respectively. As shown in FIG. 1A, along the vertical direction Y, the hook 2 is composed of the pressing portion 22, the body 21, the cushion structure 24 and the cantilever 23 sequentially.

FIG. 1B is a schematic enlarged diagram of the hook 2 in FIG. 1A. In this embodiment, the cushion structure 24 is connected to the body 21 and the cantilever 23. One end of the cantilever 23 includes a contact surface 231 and the other end of the cantilever 23 includes a cantilever root 232 connected to the cushion structure 24. Besides, the size of the cantilever root 232 and the cushion structure 24 is less than that of the cantilever 23 and the body 21. The cushion structure 24 can be made by an elastic material, which is, for example but not limited to, plastic material, rubber, silica gel or their combinations. Herein for example, the whole hook 2 (including the cushion structure 24) is made by plastic material, and the cantilever root 232 and the cushion structure 24 can form an elastic structure because the cantilever root 232 and the cushion structure 24 are disposed between the cantilever 23 and the body 21 by being reduced in size. Favorably, the cantilever root 232 has a smaller wall thickness so that the elastic cushion provided between the body 21 and the cantilever 23 can be further enhanced, and therefore the cantilever 23 has more flexibility, operating flexibly to approach or leave the body 21.

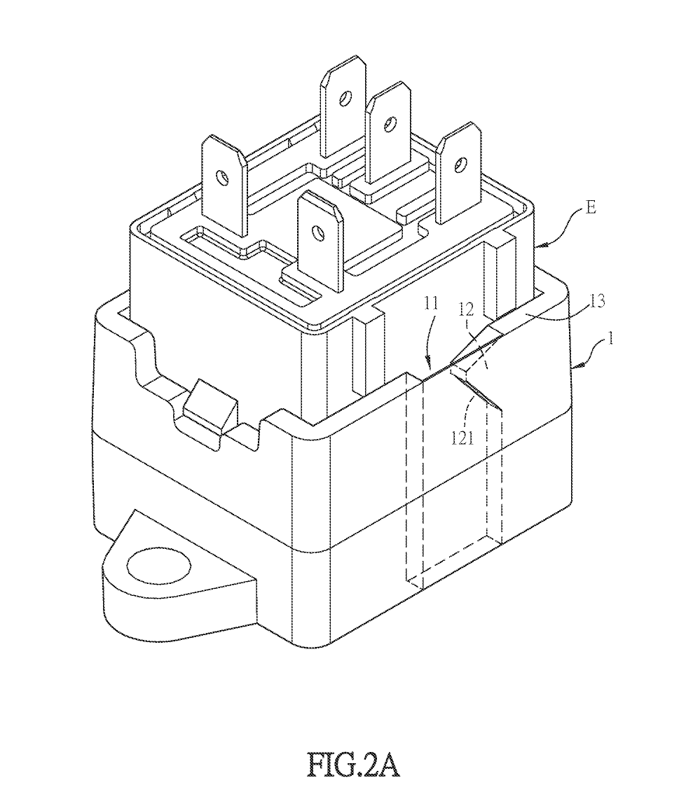

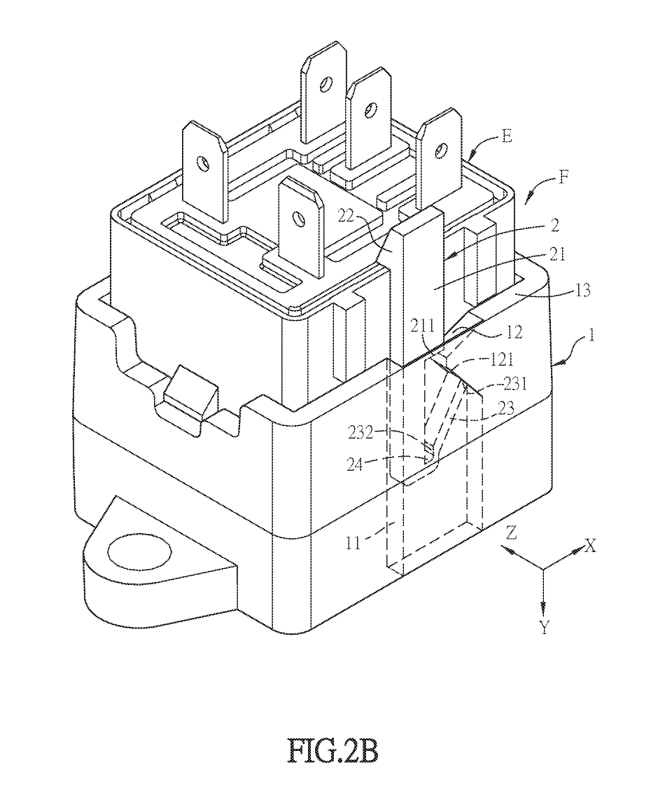

FIG. 2A is a schematic diagram showing the case after assembling the main body and the electronic element in FIG. 1A, and FIG. 2B is a schematic diagram showing the case after assembling the fixing device and the electronic element in FIG. 1A. As shown in FIGS. 1A, 2A and 2B, when the electronic element E is disposed in the space S (as FIG. 2A), the guiding groove 11 will be located between the main body 1 and the electronic element E and the block 12 will be located on a side of the guiding groove 11. As shown in FIGS. 1A and 2B, the block 12 has a blocking surface 121 corresponding to the guiding groove 11, and when the hook 2 is disposed in the guiding groove 11, the contact surface 231 of the cantilever 23 contacts the blocking surface 121. In other words, after the hook 2 is disposed in the guiding groove 11, the contact surface 231 is disposed corresponding to the blocking surface 121. Besides, the pressing portion 22 and the cantilever 23 are extended from the body 21 along different directions. As an embodiment, the pressing portion 22 is extended from the body 21 along the Z direction, and the cantilever 23 is extended from the body 21 along the X direction. In this case, the pressing portion 22 can press the electronic element E while the cantilever 23 is disposed in the guiding groove 11 and the contact surface 231 contacts the blocking surface 121.

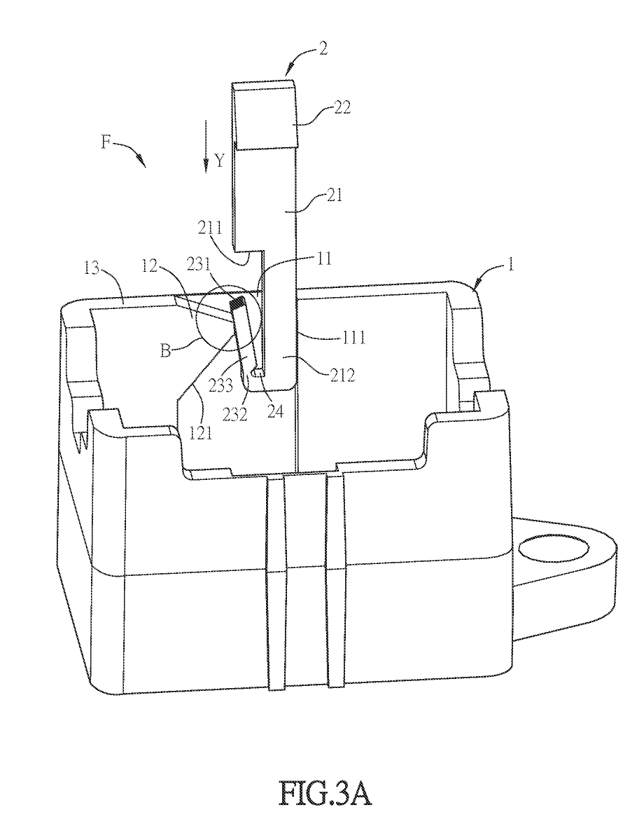

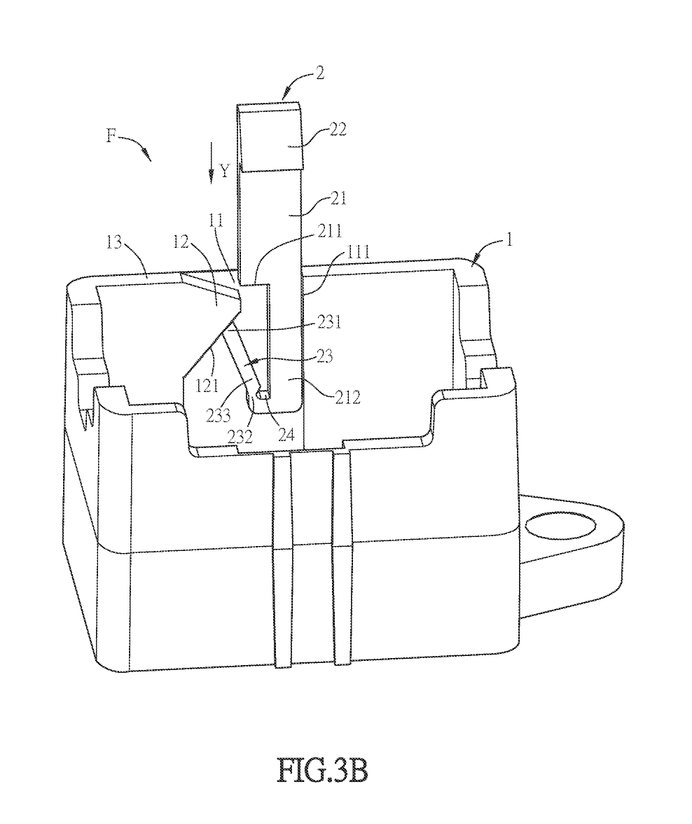

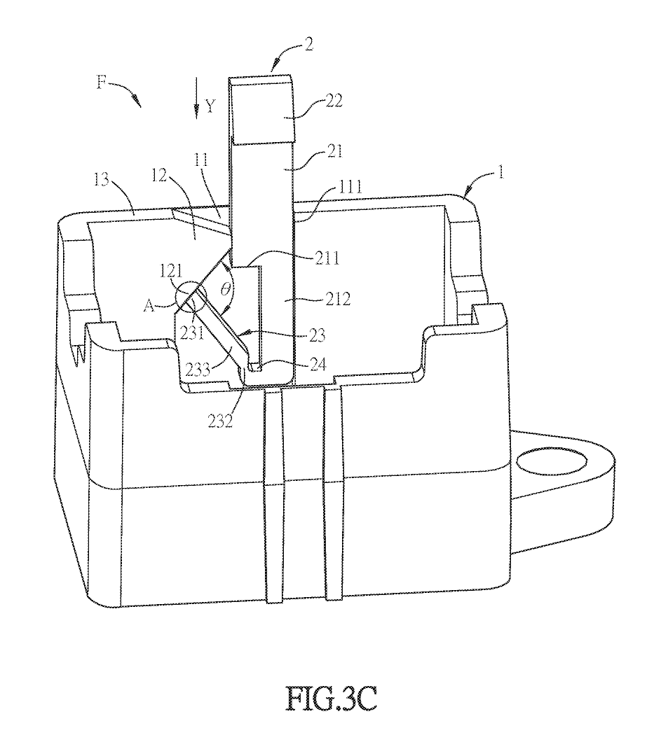

FIGS. 3A to 3C are schematic diagrams showing the operation of the fixing device in FIG. 1A. FIG. 3A shows that the hook 2 starts to be disposed in the main body 1, and FIGS. 3B and 3C show the hook 2 slides into the guiding groove 11 downwardly. As shown in FIG. 3A, the hook 2 is disposed in the guiding groove 11 correspondingly and then applied with a downward force (along the Y direction), and meanwhile the cantilever 23 is pressed by the block 12 at a compressed state so as to approach the body 21 due to its elasticity caused by the less-sized cushion structure 24. By continuously applying the force along the Y direction to the hook 2, as shown in FIG. 3B, the hook 2 is gradually forced to enter into the guiding groove 11. Favorably, the blocking surface 121 of this embodiment is an inclined surface inclining away from the sidewall 111 of the guiding groove 11, so the cantilever 23 can be released from the compression provided by the block 12 when entering into the region of the blocking surface 121. Then, the contact surface 231 of the cantilever 23 presses against the blocking surface 121 while the cantilever 23 gradually rotates around the cushion structure 24 as the pivot and away from the body 21 (from FIG. 3B to FIG. 3C) until the pressing portion 22 presses the top end of the electronic element E (as shown in FIG. 2B). Thereby, the electronic element E is fixed in the main body 1 by pressing portion 22. In other words, when the hook 2 fixes the electronic element E, the pressing portion 22 locks the top end of the electronic element E and the contact surface 231 of the cantilever 23 presses against the blocking surface 121. Besides, as shown in FIG. 3C, when the hook 2 fixes the electronic element E and the contact surface 231 presses the blocking surface 121, an included angle θ is formed between the cantilever 23 and the blocking surface 121. The included angle θ is favorably between 60° and 100°.

Furthermore, because the cantilever 23 moves away from the body 21 and the contact surface 231 presses the blocking surface 121, the hook 2 is fixed in the guiding groove 11. Besides, during the process of downwardly disposing the hook 2 into the guiding groove 11, the reaction force resulted from the contact surface 231 pressing the blocking surface 121 can push the body 21 of the hook 2 towards the direction of the sidewall 111 so that the hook 2 can be stably fixed in the guiding groove 11 and won't be removed unless additional tools are used. In this embodiment, the hook 2 is detachably disposed in the guiding groove 11. Favorably, the electronic element E is put in the space S (as shown in FIG. 2A) first, and the hook 2 is then disposed in the guiding groove 11 (as shown in FIG. 2B). When the cantilever 23 enters into the region of the blocking surface 121, the contact surface 231 of the cantilever 23 presses the blocking surface 121 and the cantilever 23 can, as shown in FIGS. 3B and 3C, rotate around the cushion structure 24 as the pivot to move away from the body 21, which indicates that the angle formed between the body 21 and the cushion 24 and cantilever 23 is gradually increased. Accordingly, the pressing portion 22 can be located at different heights when the above-mentioned angle is changed (which means the contact surface 231 presses different portions of the blocking surface 121), and therefore this embodiment can be applied to the electronic elements E having different heights.

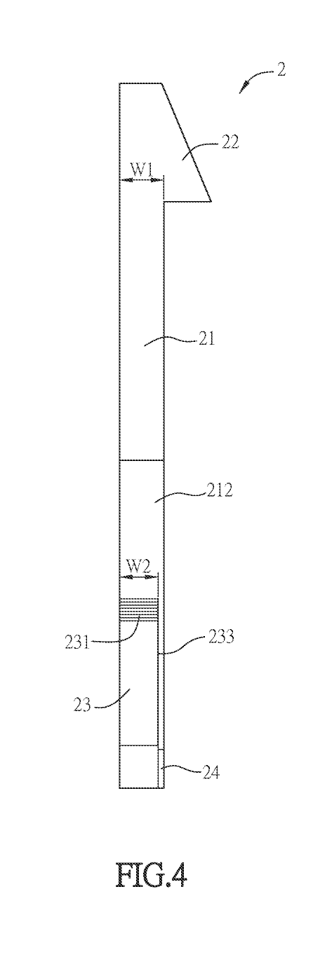

In addition, when the electronic element E is disposed in the space S of the main body 1 and fixed by the pressing portion 22, the pressing portion 22 and the major part of the body 21 will directly contact the electronic element E. As shown in FIGS. 2B and 3B, the side of the body 21 contacting the electronic element E has a first plane 212, and the side of the cantilever 23 near the electronic element E has a second plane 233 which doesn't contact the electronic element E. FIG. 4 is a schematic diagram showing another view, from the cantilever 23 to the body 21, of the hook in FIG. 1B. In FIGS. 3B and 4, as an embodiment, the cushion structure 24, from the end near the body 21 to the cantilever 23, gradually inclines towards the direction of the guiding groove 11 (i.e. inclining away from the electronic element E as shown in FIG. 2B), and therefore the first plane 212 and the second plane 233 are not on the same plane. Besides, the second plane 233 is to the direction of the guiding groove 11 (i.e. away from the electronic element E as shown in FIG. 2B) more than the first plane 212. A width W1 of the body 21 is greater than a width W2 of the cantilever 23 and the cantilever 23 is parallel to the surface of the body 21 contacting the guiding groove 11 (“parallel” means on the same plane), so the second plane 233 of the cantilever 23 is away from the electronic element E. By the disposition of the second plane 233 farther from the electronic element E than the first plane 212, the cantilever 23 will not contact the electronic element E. Therefore, the heat conducted to the cantilever 23 can be reduced, so the holding force of the cantilever root 232 can be maintained and the lifespan of the hook 2 can be expanded.

Besides, the end of the body 21 near the cantilever 23 has an indentation 211. The cushion structure 24 is disposed in the indentation 211 and connected to the body 21, and the length of the indentation 211 is greater than that of the cantilever 23. Hence, when the cantilever 23 undergoes the force towards the body 21 provided by the block 12, the cushion structure 24 and the partial cantilever 23 can be contained by the indentation 211. The design of the cushion structure 24 and indentation 211 can not only increase the flexibility of the cantilever 23 but also avoid the tolerance. In the case without the design of the indentation 211, when the hook 2 starts to be put in the guiding groove 11 (as shown in FIG. 3A) and the cantilever 23 is then pressed by the block 12, the cantilever 23 will approaches the body 21 too much and a stress will be thus generated to push the hook 2 upwards. Therefore, the pressing portion 22 will be lifted and a tolerance will be generated so that the electronic element E can't be effectively pressed by the pressing portion 22.

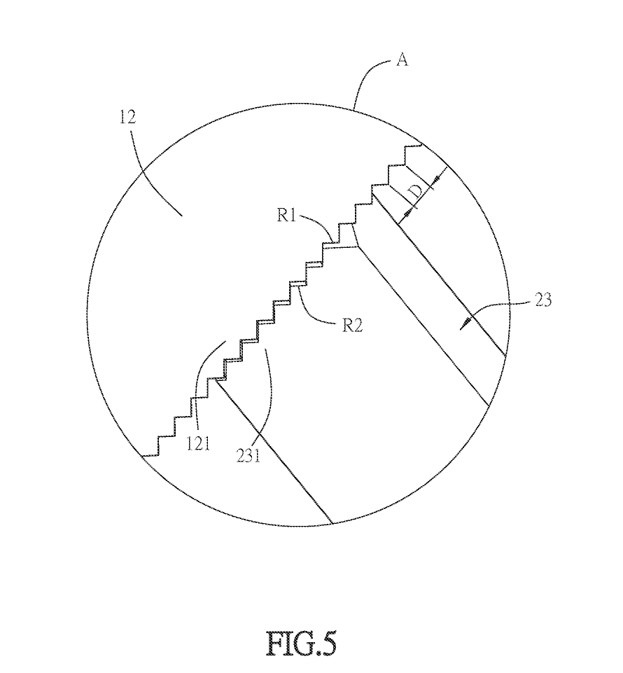

In addition to that the indentation 211 can avoid the occurrence of the tolerance, the fixing device F of this embodiment can further include other mechanisms to reduce the tolerance. FIG. 5 is a schematic enlarged diagram of the region A of the fixing device in FIG. 3C. As shown in FIGS. 3C and 5, the blocking surface 121 of the block 12 includes a first rough structure R1, and the contact surface 231 of the cantilever 23 includes a second rough structure R2. Favorably, the first rough structure R1 and the second rough structure R2 match each other. Under the case without any other external force, these matched rough structures can fix the relative position of the hook 2 and the main body 1, so that the hook 2 will not be easily displaced when the pressing portion 22 presses and fixes the electronic element E. In this embodiment, the first and second rough structures R1 and R2 include a plurality of parallel tooth-like portions. The interval D between the tooth-like portions is not limited here, and favorably is less than 0.1 mm. Herein, the interval D denotes the interval between the tips of the adjacent tooth-like portions. Therefore, the tolerance between the pressing portion 22 and the electronic element E can be reduced under 0.1 mm when the fixing device F and the electronic element E are assembled (as shown in FIG. 2B). As an embodiment, when the pressing portion 22 approaches the electronic element E, the pressing portion 22 can move downwards for one or more intervals D (a single interval D is regarded as a unit) so as to be more attached to the electronic element E. Therefore, when the interval D of the first and second rough structures R1 and R2 is smaller, the tolerance between the pressing portion 22 and the electronic element E can be reduced more.

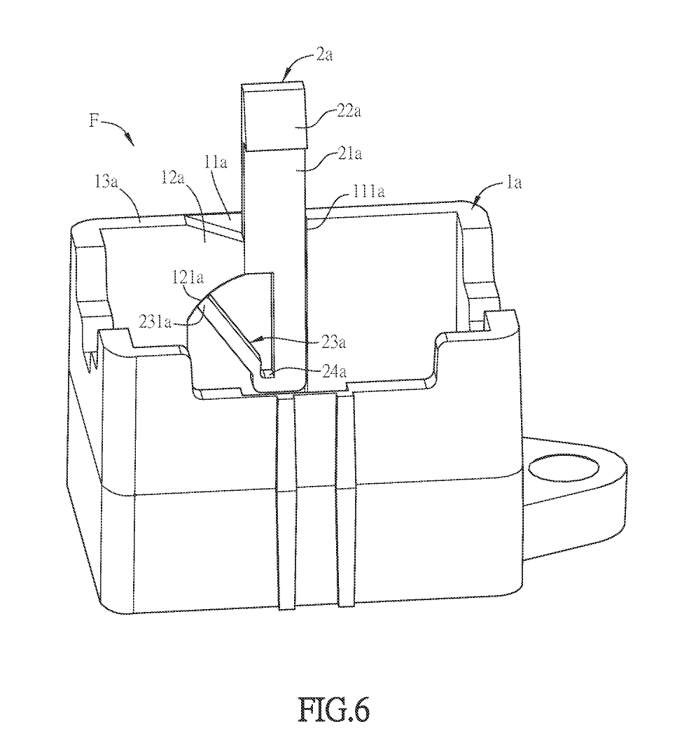

FIG. 6 is a schematic diagram of a fixing device according to another embodiment of the invention. As shown in FIG. 6, the blocking surface 121a of the block 12a of this embodiment is a curved surface, and is favorably a concave surface concaved away from the sidewall 111a. In this case, the cantilever 23a also can rotate around the cushion structure as the pivot and away from the body 21a. However, the invention is not limited thereto.

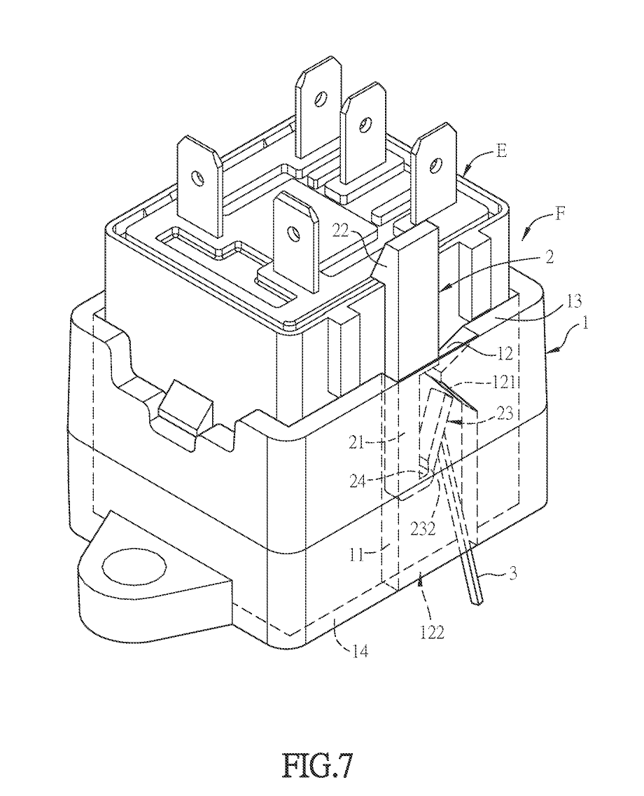

FIG. 7 is a schematic diagram of a disassembling tool for the fixing device in FIG. 2B. As shown in FIG. 7, the main body 1 of this embodiment further includes an opening 122. The opening 122 can be disposed at a bottom 14 or the sidewall 13 of the main body 1 or can be used as the passage for the circuit or wires, but however the invention is not limited thereto. The disassembling tool 3 passes through the opening 122 to press the hook 2. In this embodiment, the opening 122 is disposed at the bottom of the guiding groove 11 and corresponding to the blocking surface 121, and the disassembling tool 3 can pass through the opening 122 to touch and press the hook 2. Favorably, the disassembling tool 3 presses the cantilever 23 of the hook 2 so as to force the cantilever 23 to move towards the body 21 so that the cantilever 23 can be disposed in the indentation 211 and the hook 2 can be taken out. The disassembling tool 3 can be, for example but is not limited to, a flathead screwdriver, a file, or the like (having a flat surface). For this kind of disassembling method, the electronic element E can be taken out without pushing or pulling the body 21 of the hook 2 to avoid the damage of the body 21. To be noted, the opening 122 corresponding to the blocking surface 121 as mentioned above doesn't mean the opening 122 needs to be located directly below the blocking surface 121. In other embodiments, the opening 122 can be disposed at the sidewall of the main body 1 as long as the disassembling tool 3 can press the cantilever 23. Favorably, the disassembling tool 3 can touch the blocking surface to make sure the cantilever 23 can be forced to move towards the body 21 by the disassembling tool 3.

In summary, the fixing device of the invention includes a main body for containing an electronic element. The main body includes the guiding groove disposed between the main body and the electronic element so that the electronic element can be fixed when the hook is disposed in the guiding groove and the pressing portion presses the top end of the electronic element. In this case, the electronic element is first disposed in the main body and the hook is then disposed in the guiding groove, and therefore the electronic element can be settled during the assembly process without pushing or pulling the body of the hook. Hence, the damage of the hook can be reduced so that the lifespan of the fixing device and the hook can be expanded.

Besides, the contact surface of the cantilever can press the blocking surface of the guiding groove, so that the cantilever will move away from the body during the process of disposing the hook into the guiding groove. Therefore, the heat conducted to the cantilever through the body from the electronic element can be reduced, so the holding force of the cantilever can be maintained and the lifespan of the hook can be expanded.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A fixing device of electronic element, comprising:
a main body containing an electronic element and comprising:
a guiding groove disposed at a sidewall of the main body; and
a block disposed on a side of the guiding groove and having a blocking surface; and
a hook disposed in the guiding groove to fix the electronic element and comprising:
a body;
a pressing portion disposed on one end of the body;
a cantilever having a contact surface to press the blocking surface; and
a cushion structure, two ends of which are connected to the other end of the body and the cantilever, respectively.

2. The fixing device of electronic element as recited in claim 1, wherein the end of the body near the cantilever has an indentation, the cushion structure is disposed in the indentation and connected to the body, and the length of the indentation is greater than that of the cantilever.

3. The fixing device of electronic element as recited in claim 1, wherein the hook is detachably disposed in the guiding groove.

4. The fixing device of electronic element as recited in claim 1, wherein the cantilever includes a cantilever root connected to the cushion structure, and the size of the connection portion of the cantilever root and the cushion structure is less than that of the cantilever and the body.

5. The fixing device of electronic element as recited in claim 1, wherein the blocking surface has a rough structure.

6. The fixing device of electronic element as recited in claim 1, wherein the contact surface of the cantilever has a second rough structure.

7. The fixing device of electronic element as recited in claim 1, wherein the blocking surface is an inclined surface or a curved surface.

8. The fixing device of electronic element as recited in claim 1, wherein when the hook fixes the electronic element, the pressing portion locks the top end of the electronic element and the contact surface of the cantilever presses the blocking surface.

9. The fixing device of electronic element as recited in claim 1, wherein when the hook fixes the electronic element, an included angle is formed between the cantilever and the blocking surface and the included angle is between 60° and 100°.

10. The fixing device of electronic element as recited in claim 1, wherein the pressing portion and the cantilever are extended from the two ends of the body, respectively.

11. The fixing device of electronic element as recited in claim 10, wherein the pressing portion and the cantilever are extended from the body along different directions.

12. The fixing device of electronic element as recited in claim 1, wherein the main body further includes an opening, and the opening is disposed at a bottom or the sidewall of the main body.

13. The fixing device of electronic element as recited in claim 12, further comprising:
a disassembling tool passing through the opening to press the cantilever.

14. The fixing device of electronic element as recited in claim 1, wherein the body has a first plane contacting the electronic element, and the side of the cantilever near the electronic element has a second plane which doesn't contact the electronic element.

15. The fixing device of electronic element as recited in claim 14, wherein the second plane is farther from the electronic element than the first plane.

16. The fixing device of electronic element as recited in claim 14, wherein a width of the body is greater than that of the cantilever.

17. The fixing device of electronic element as recited in claim 1, wherein the cushion structure is made by an elastic material.

18. The fixing device of electronic element as recited in claim 17, wherein the elastic material includes plastic material, rubber, silica gel or their combinations.

19. A fixing device of electronic element, comprising:
a main body containing an electronic element and comprising:
a guiding groove disposed at a sidewall of the main body; and
a block disposed on a side of the guiding groove and having a blocking surface; and
a hook used to fix the electronic element and comprising:
a body including an indentation;
a pressing portion disposed on one end of the body;
a cantilever having a contact surface; and
a cushion structure, two ends of which are connected to the other end of the body and the cantilever, respectively, wherein when the hook is disposed in the guiding groove, the cantilever is pressed to the indentation by the block, and when the pressing portion fixes the electronic element, the contact surface of the cantilever presses the blocking surface.
